(19) United States
(12) Patent Application Publication
(10) Pub. No.: US 2018/0238632 A1
(43) Pub. Date: Aug. 23, 2018

(54) HEAT PIPE, RADIATOR, AND ELECTRONIC DEVICE

(71) Applicant: Lenovo (Beijing) Co., Ltd., Beijing (CN)

(72) Inventors: Zizhou JIA, Beijing (CN); Ying SUN, Beijing (CN)

(21) Appl. No.: 15/809,436

(22) Filed: Nov. 10, 2017

(30) Foreign Application Priority Data
Feb. 21, 2017 (CN) 201710092921.9

(51) Int. Cl. F28D 15/02; F28D 15/04; G06F 1/20; H05K 7/20

(52) U.S. Cl. CPC F28D 15/0241; F28D 15/046; H05K 7/20336; G06F 1/20; G06F 1/203

(57) ABSTRACT

The present disclosure provides a heat pipe suitable for heat conduction in deformable systems. The heat pipe includes a pipe shell and a liquid-absorption core on the inner wall of the pipe shell. The pipe shell includes a first pipe section at an evaporation end of the heat pipe, a second pipe section at a condensation end of the heat pipe, and an intermediate pipe section connecting the first pipe section and the second pipe section. The intermediate pipe section of the pipe shell is an intermediate flexible pipe, and the liquid-absorption core has a flexible structure.

### CROSS-REFERENCES TO RELATED APPLICATIONS

This application claims priority of Chinese Patent Application No. 201710092921.9 filed on Feb. 21, 2017, the entire contents of which are hereby incorporated by reference.

### FIELD OF THE DISCLOSURE

The present disclosure generally relates to the field of computer accessories technology and, more particularly, relates to a heat pipe, a radiator, and an electronic device.

### BACKGROUND

Because of the excellent thermal conductivity, heat pipes have been widely used for heat dissipation, especially in thin systems. A heat pipe is typically formed by a closed pipe shell and a liquid-absorption core on the inner wall of the pipe shell. The inside of the heat pipe is pumped to have a negative pressure and then filled with an appropriate liquid. The liquid may have a low boiling point, and thus may easily evaporate. Moreover, the heat pipe has an evaporation end and a condensation end. When the evaporation end of the heat pipe is heated, the liquid in the heat pipe evaporates rapidly. The steam of the liquid flows to the other end (i.e., the condensation end) driven by a small pressure difference. In the meantime, by releasing the heat, the steam may be re-condensed into the liquid state. The re-condensed liquid further flows back to the evaporation end along the liquid-absorption core due to the capillary attraction of the liquid-absorption core. As the conduction cycle continuously runs, heat conduction is realized.

In conventional heat pipes, the capillary layer of the liquid-absorption core may be formed by introducing grooves or sintered copper powder into the copper pipe. However, this type of heat pipe is rigid, and the overall shape cannot be re-adjusted after the formation. Thus, the conventional heat pipes cannot be used for heat conduction in deformable systems.

Therefore, how to provide a shape-adjustable heat pipe to accommodate the requirements for the heat conduction in deformable systems is an urgent problem to be solved in the field. The disclosed heat pipe, radiator, and electronic device are directed to solve one or more problems set forth above and other problems.

### BRIEF SUMMARY OF THE DISCLOSURE

One aspect of the present disclosure provides a heat pipe. The heat pipe includes a pipe shell and a liquid-absorption core on the inner wall of the pipe shell. The pipe shell includes a first pipe section at an evaporation end of the heat pipe, a second pipe section at a condensation end of the heat pipe, and an intermediate pipe section connecting the first pipe section and the second pipe section. The intermediate pipe section of the pipe shell is an intermediate flexible pipe, and the liquid-absorption core has a flexible structure.

Another aspect of the present disclosure provides a radiator. The radiator includes a heat pipe. The heat pipe includes a pipe shell and a liquid-absorption core on the inner wall of the pipe shell. The pipe shell includes a first pipe section at an evaporation end of the heat pipe, a second pipe section at a condensation end of the heat pipe, and an intermediate pipe section connecting the first pipe section and the second pipe section. The intermediate pipe section of the pipe shell is an intermediate flexible pipe, and the liquid-absorption core has a flexible structure.

Another aspect of the present disclosure provides an electronic device. The electronic device includes a radiator. A heat pipe of the radiator includes a pipe shell and a liquid-absorption core on the inner wall of the pipe shell. The pipe shell includes a first pipe section at an evaporation end of the heat pipe, a second pipe section at a condensation end of the heat pipe, and an intermediate pipe section connecting the first pipe section and the second pipe section. The intermediate pipe section of the pipe shell is an intermediate flexible pipe, and the liquid-absorption core has a flexible structure.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic structural view of a heat pipe consistent with some embodiments of the present disclosure;

FIG. 2 illustrates an enlarged structural view of part A of the heat pipe shown in FIG. 1;

FIG. 3 illustrates a schematic structural view of another heat pipe consistent with some embodiments of the present disclosure;

FIG. 4 illustrates an enlarged structural view of part B of the heat pipe shown in FIG. 3;

FIG. 5 illustrates a schematic structural view of another heat pipe consistent with some embodiments of the present disclosure; and

FIG. 6 illustrates an enlarged structural view of part C of the heat pipe shown in FIG. 5.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts. The described embodiments are some but not all of the embodiments of the present disclosure. Based on the disclosed embodiments and without inventive efforts, persons of ordinary skill in the art may derive other embodiments consistent with the present disclosure, all of which are within the scope of the present disclosure.

The disclosed embodiments in the present disclosure are merely examples for illustrating the general principles of the disclosure. Any equivalent or modification thereof, without departing from the spirit and principle of the present disclosure, falls within the true scope of the present disclosure.

The present disclosure provides a shape-adjustable heat pipe that can be used for heat conduction in deformable systems. The shape-adjustable heat pipe may include a pipe shell and a liquid-absorption core arranged on the inner wall of the pipe shell. The pipe shell may include a first pipe section at the evaporation end of the heat pipe, a second pipe section at the condensation end of the heat pipe, and an intermediate pipe section connecting the first pipe section and the second pipe section. The intermediate pipe section may be an intermediate flexible pipe. The liquid-absorption core may also have a flexible structure. In one embodiment, the intermediate flexible pipe of the intermediate pipe section may be configured as a center portion between the first pipe section and the second pipe section of the pipe shell. In this case, the intermediate pipe section may be a center flexible pipe.

The intermediate flexible pipe and the liquid-absorption core of the disclosed heat pipe are both flexible. As such, the shape of the center part of the pipe shell may be able to change as the shape of the deformable system changes. Therefore, the heat pipe may be suitable for heat conduction in the deformable system.

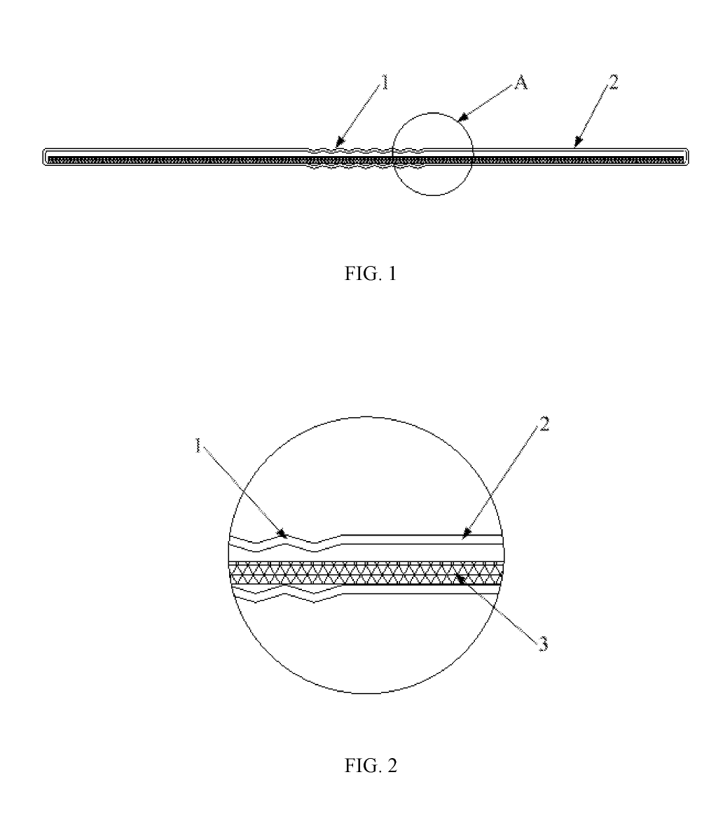

In one embodiment, the intermediate pipe section of the pipe shell may be a metal bellows to achieve flexibility. FIG. 1 shows a schematic cross-section view of a heat pipe consistent with some embodiments of the present disclosure. FIG. 2 shows an enlarged structural view of part A of the heat pipe shown in FIG. 1.

Referring to FIGS. 1-2, the heat pipe may include a pipe shell (not labeled) and a liquid-absorption core 3 on the inner wall of the pipe shell. The pipe shell of the heat pipe may include an intermediate flexible pipe, such as a center flexible pipe 1, including for example, a metal bellows. The pipe shell of the heat pipe may also include a first pipe section 2 and a second pipe section 2, which may be, for example, rigid metal pipes. By using the metal bellows to form the intermediate pipe section (i.e., the center flexible pipe 1) and using the rigid metal pipes to form the first pipe section 2 and the second pipe section 2, respectively, the center part of the pipe shell may be deformed as desired while the shape of the pipe shell at each end may remain unchanged. As such, the heat pipe may be conducive to fixing the evaporation end and the condensation end of the heat pipe. In addition, because the entire pipe shell is made of metal materials, heat transfer in the heat pipe may be quick and the fabrication of the pipe shell may be easy.

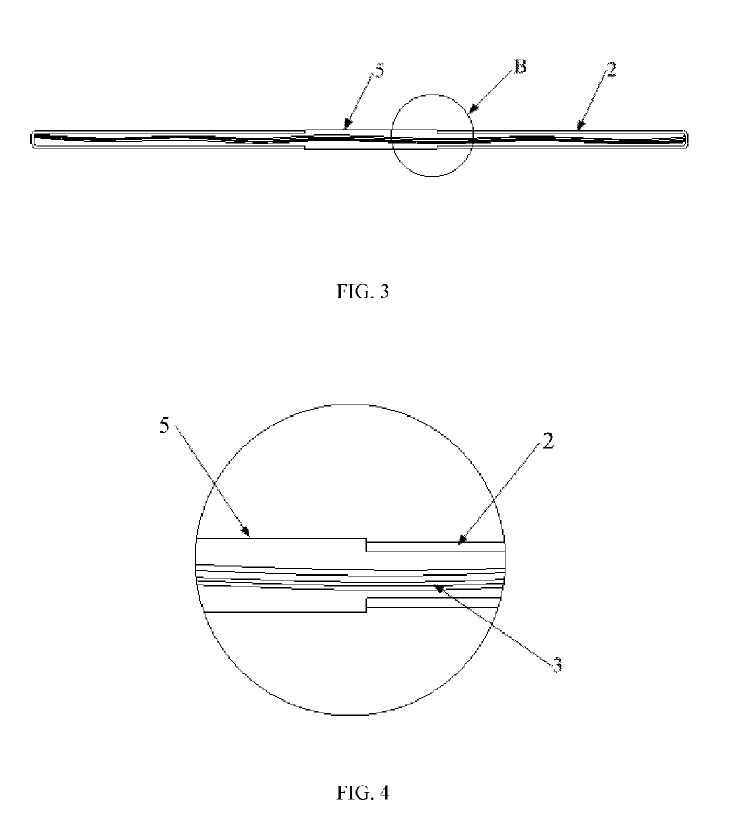

In another embodiment, the center flexible pipe of the heat pipe is a flexible non-metal pipe, and the first pipe section and the second pipe section may be rigid metal pipes. FIG. 3 shows a schematic cross-section view of a heat pipe consistent with some embodiments of the present disclosure. FIG. 4 shows an enlarged structural view of part B of the heat pipe shown in FIG. 3.

Referring to FIGS. 3-4, the heat pipe may include a pipe shell (not labeled) and a liquid-absorption core 3 on the inner wall of the pipe shell. The pipe shell of the heat pipe may include a center flexible pipe 5, including for example, a flexible non-metal pipe. The pipe shell of the heat pipe may also include a first pipe section 2 and a second pipe section 2, which may be rigid metal pipes. By using a flexible non-metal pipe, such as a rubber pipe or a nylon pipe with desired flexibility, to form the intermediate pipe section (i.e. the center flexible pipe 5) of the heat pipe and using two rigid metal pipes, such as two copper pipes, to form the first pipe section 2 and the second pipe section 2 of the pipe shell, the shape of the center part of the pipe shell may be able to change, but the two end sections of the pipe shell (i.e., the first pipe section and the second pipe section) may not be flexible. As such, the heat pipe may be conducive to fixing the evaporation end and the condensation end of the heat pipe. Moreover, because the intermediate pipe section is made of non-metal materials, the heat pipe is partially made of metals and partially made of non-metals. Therefore, besides conducting heat, the heat pipe may also be able to reduce the overall weight.

Moreover, through a fabrication process including mold injection, plastic wrapping, hot melting, etc., the flexible non-metal pipe (i.e. the center flexible pipe 5) and the two rigid metal pipes (i.e. the first pipe section 2 and the second pipe section 2) may be formed into a single piece to ensure desired tightness of the pipe shell and also make the fabrication easy to process.

In other embodiments, in order to expand the deformable range of the pipe shell, the first pipe section 2 and the second pipe section 2 may be end flexible pipes. As such, the entire pipe shell may be flexible. That is, corresponding to changes in the deformable system, the pipe shell can be deformed at any position along the length direction of the pipe shell. Therefore, the heat pipe may be more suitable for heat conduction in deformable systems.

For example, the center flexible pipe 5 of the pipe shell may be a non-metal bellows, and each end flexible pipe may be a metal bellows. In one embodiment, the entire pipe shell may have a corrugated structure. The two end sections (i.e., the first pipe section 2 and the second pipe section 2) of the pipe shell may be made of a metal, such as Cu, and the center section (i.e., the intermediate pipe section) of the pipe shell may be made of a non-metallic material, such as rubber. As such, the corrugated pipe shell that is made partially of metal and partially of non-metal may be able to ensure the heat conduction in the heat pipe, and also reduce the weight of the pipe shell. Moreover, through a fabrication process including mold injection, plastic wrapping, hot melting, etc., the non-metal bellows and the two metal bellows may be formed into a single piece to ensure desired tightness of the pipe shell.

In addition, similar to the end flexible pipes described above, the intermediate flexible pipe may also be a metal bellows. Accordingly, the entire pipe shell may be a one-piece metal bellows. As such, the structure may be simple and the fabrication may be easy to process.

In other embodiments, as long as the intermediate pipe section of the pipe shell is flexible, one or both of the first pipe section and the second pipe section can be rigid, and the corresponding heat pipe is also consistent with the present disclosure.

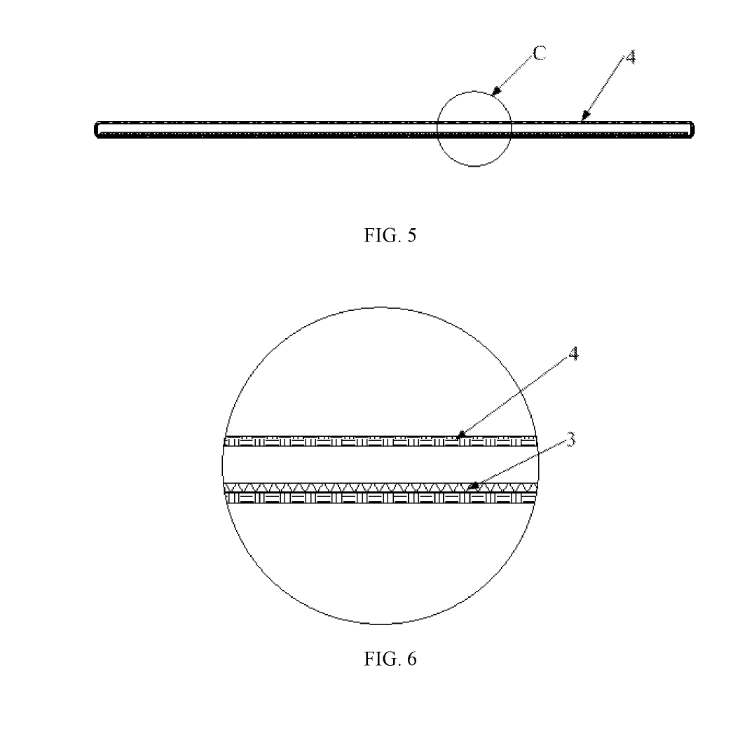

In another embodiment, the flexibility of the pipe shell may be achieved by using a metal braiding method to form the pipe shell. FIG. 5 shows a schematic cross-section view of a heat pipe consistent with some embodiments of the present disclosure. FIG. 6 shows an enlarged structural view of part C of the heat pipe shown in FIG. 5.

Referring to FIGS. 5-6, the heat pipe may include a pipe shell (not labeled) and liquid-absorption core 3 on the inner wall of the pipe shell. The pipe shell of the heat pipe may be a one-piece metal braided pipe 4. Therefore, the pipe shell of the heat pipe can be deformed at any position along the length direction of the pipe shell. As such, the heat pipe including the metal braided pipe 4 may have desired structural strength, and thus a longer service life.

Optionally, the liquid-absorption core 3 of the heat pipe may be a fiber-braided capillary layer. By forming the liquid-absorption core 3 through fiber braiding, the liquid-absorption core 3 may simultaneously have desired capillary force for the liquid and desired adhesive property to stay on the pipe shell. Therefore, when the heat pipe is used for heat conduction in deformable systems, the performance reliability may be ensured. Alternatively, when the pipe shell is a one-piece metal pipe, the liquid-absorption core may also be grooves or a sintered copper powder layer on the inner wall of the metal pipe.

Further, referring to FIG. 2, in one embodiment, the liquid-absorption core 3 may be a fiber-braided capillary layer having a three-dimensional (3D) network structure formed by tightly-braided fibers. By using the 3D braiding method to form the fiber-braided capillary layer, the fiber-braided capillary layer may have desired anti-flattening and anti-bending performance so that the liquid-absorption core may be tightly attached on the inner wall of the pipe shell, and thus a desired gas-liquid channel may be formed. In addition, the capillary phenomenon may also be enhanced. In other embodiments, the fiber-braided capillary layer may be a network formed by two-dimensional (2D) fiber braiding (referring to FIG. 6) or may be formed by parallelly arranged fibers (referring to FIG. 4). Specifically, as long as a capillary layer is formed, the heat pipe including the formed capillary layer is consistent with the disclosed embodiments.

Optionally, the fiber-braided capillary layer may be a 3D copper fiber mesh. By using copper fibers to form the fiber-braided capillary layer through 3D braiding, the cost may be low and the formed 3D copper fiber mesh may be durable. In other embodiments, the fiber-braided capillary layer may be formed by aluminum fibers or any other appropriate fibers.

The present disclosure also provides a radiator. The radiator may include a heat pipe consistent with various embodiments of the present disclosure. The heat pipe may be flexible, and thus may be suitable for heat conduction in deformable systems. The advanced properties of the radiator are related to the features of the disclosed heat pipe, and thus may be referred to the corresponding contents in the above description of the heat pipe.

In addition, the present disclosure also provides an electronic device. The electronic device may include a radiator consistent with various embodiments of the present disclosure. The radiator may include a disclosed heat pipe. The heat pipe may be flexible to accommodate deformable systems heat conduction. The advanced properties of the electronic device are related to the features of the disclosed radiator, and thus related to the features of the disclosed heat pipe. Therefore, the advanced properties of the electronic device may be referred to the corresponding contents in the above description of the heat pipe and the radiator.

For example, the electronic device may be a notebook computer including the disclosed radiator or heat pipe, such that the notebook computer may be used in deformable systems. Therefore, the notebook computer including the disclosed radiator provides an additional product type and is easy to carry around. Moreover, the electronic device may be a desktop computer configured with the disclosed radiator or heat pipe within the computer case. In other embodiments, the electronic device may be a refrigerator, an air conditioner, or any other cooling device, that is configured with the disclosed radiator or heat pipe.

Compared to conventional heat pipes, radiators, and electronic devices, the disclosed heat pipes, radiators, and electronic devices may demonstrate several advantages.

According to the disclosed heat pipe, the heat pipe includes a pipe shell and a liquid-absorption core arranged on the inner wall of the pipe shell. The pipe shell includes a first pipe section close to the evaporation end of the heat pipe, a second pipe section closed to the condensation end of the heat pipe, and an intermediate pipe section connecting the first pipe section and the second pipe section. The intermediate pipe section is an intermediate flexible pipe (e.g., a center flexible pipe) and the liquid-absorption core is also flexible.

According to the disclosed heat pipe, the center flexible pipe and the liquid-absorption core of the disclosed heat pipe are both flexible. As such, the shape of the center part of the pipe shell may be able to change as the shape of the deformable system changes. Therefore, the heat pipe may be suitable for heat conduction in deformable systems.

Further, according to the disclosed radiator, the radiator includes a heat pipe that is consistent with various embodiments of the present disclosure. Therefore, the radiator may be suitable for heat conduction in deformable systems.

Moreover, according to the disclosed electronic device, the electronic includes a radiator that is consistent with various embodiments of the present disclosure, and thus includes a disclosed heat pipe. Therefore, the electronic device may be suitable for heat conduction in deformable systems.

Further, in the present disclosure, relational terms such as first, second, and the like, may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

Various embodiments of the present specification are described in a progressive manner, in which each embodiment focusing on aspects different from other embodiments, and the same and similar parts of each embodiment may be referred to each other. Because the disclosed devices correspond to the disclosed methods, the description of the disclosed devices and the description of the disclosed methods may be read in combination or in separation.

The description of the disclosed embodiments is provided to illustrate the present invention to those skilled in the art. Various modifications to these embodiments will be readily apparent to those skilled in the art, and the generic principles determined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A heat pipe, comprising:
a pipe shell including a first pipe section at an evaporation end of the heat pipe, a second pipe section at a condensation end of the heat pipe, and an intermediate pipe section connecting the first pipe section and the second pipe section; and
a liquid-absorption core on an inner wall of the pipe shell, wherein:
the intermediate pipe section of the pipe shell is an intermediate flexible pipe; and
the liquid-absorption core has a flexible structure.

2. The heat pipe according to claim 1, wherein:
the intermediate flexible pipe includes metal bellows; and
the first pipe section and the second pipe section are rigid metal pipes.

3. The heat pipe according to claim 1, wherein:
the intermediate flexible pipe is a non-metal pipe; and
the first pipe section and the second pipe section are rigid metal pipes.

4. The heat pipe according to claim 3, wherein:
the non-metal pipe and the rigid metal pipes are formed into a single-piece bellows.

5. The heat pipe according to claim 1, wherein:
each of the first pipe section and the second pipe section includes a rigid pipe and a flexible pipe.

6. The heat pipe according to claim 1, wherein:
each of the first pipe section and the second pipe section is an end flexible pipe.

7. The heat pipe according to claim 6, wherein:
the intermediate flexible pipe is a non-metal bellows, and
the end flexible pipe includes metal bellows.

8. The heat pipe according to claim 7, wherein:
the non-metal bellows and the end flexible pipes are formed into a single-piece bellows.

9. The heat pipe according to claim 6, wherein:
the intermediate flexible pipe and the end flexible pipes are metal bellows.

10. The heat pipe according to claim 9, wherein:
the metal bellows are formed into a single-piece bellows.

11. The heat pipe according to claim 6, wherein:
the intermediate flexible pipe and the end flexible pipes are metal braided pipes, and wherein the intermediate flexible pipe comprises a center flexible pipe.

12. The heat pipe according to claim 1, wherein:
the liquid-absorption core is a fiber-braided capillary layer.

13. The heat pipe according to claim 12, wherein:
the fiber-braided capillary layer is formed into a three-dimensional network structure by tightly-braided fibers.

14. The heat pipe according to claim 13, wherein:
the fiber-braided capillary layer is a three-dimensional mesh made of a metal material including copper and aluminum.

15. The heat pipe according to claim 12, wherein:
the fiber-braided capillary layer is a network formed by two-dimensional fiber braiding.

16. The heat pipe according to claim 12, wherein:
the fiber-braided capillary layer is formed by parallelly arranged fibers.

17. The heat pipe according to claim 1, wherein:
the pipe shell is a one-piece metal pipe, and
the liquid-absorption core includes grooves or a sintered copper powder layer formed on the inner wall of the metal pipe.

18. A radiator including the heat pipe according to claim 1.

19. An electronic device including the radiator according to claim 18.
